(19) United States
(12) Patent Application Publication
(10) Pub. No.: US 2010/0080902 A1
(43) Pub. Date: Apr. 1, 2010

(54) METHOD AND APPARATUS FOR LOW COST PRODUCTION OF POLYSILICON USING SIEMEN'S REACTORS

(76) Inventors: FARID ARIFUDDIN, New Delhi (IN); Mohan Chandra, Merrimack, NH (US); Sankaran Muthukrishnan, Chennai (IN)

Correspondence Address: GLOBAL IP SERVICES, PLLC, 10 CRESTWOOD LANE, NASHUA, NH, 03062, US

(21) Appl. No.: 12/239,835

(22) Filed: Sep. 29, 2008

(51) Int. Cl. C23C 16/44; C23C 16/54

(52) U.S. Cl. 427/255.11; 118/725

(57) ABSTRACT

A novel low cost polysilicon production technique for Siemens type reactors is disclosed. In one embodiment, a CVD reactor assembly includes a reactor forming a stainless steel envelope attached to a base plate. The stainless steel envelope is designed to receive a thermal fluid at room temperature and maintain a reactor wall temperature up to 450° C. A steam generator is configured to receive the thermal fluid having a temperature up to 450° C. from the reactor and generate a low pressure steam around 350° C. to 450° C. A low pressure steam turbine/generator is configured to receive the low pressure steam and generate electricity. In another embodiment, the steam generator is configured to receive heat from an external source in addition to the thermal fluid to generate super heated steam. A conventional steam turbine/generator receives the super heated steam and generates electricity.

### TECHNICAL FIELD OF THE INVENTION

The present invention relates generally to chemical vapor deposition (CVD) reactor, and more particularly relates to low cost production of polycrystalline silicon.

### BACKGROUND

One of the widely practiced conventional methods of polysilicon production is by depositing polysilicon in a CVD reactor, and is generally referred as Siemens method. In this method, polysilicon is deposited in the CVD reactor on high-purity, electrically heated thin silicon rods called “slim rods”. The reactor used for this purpose is referred to as a “cold walled reactor”.

The reactor walls are maintained by circulating water around the periphery of the reactor to take away the heat generated in the reactor by the hot silicon rods. The silicon rods are kept at temperature well above 1000° C. Since no other surface in the reactor can be kept hot as silicon can deposit on any hot surface approximately above 450° C., cooling the reactor walls is generally required to prevent silicon from depositing on the reactor walls. Further, insulating media cannot be used in the reactor for the same reason as the insulating media can get heated, resulting in possibility of contaminating the product.

While circulating cold water solves the above problems and has been the generally practiced state of the art for the past few decades, the water may also take away significant amount of energy needed to heat the silicon rods and hence the reactor may require more electrical energy to heat the silicon rods and keep them in the operating temperature. Generally, it takes several tens of kilowatt hours of energy to produce a kilogram of silicon thus making the cost of production of silicon also significantly expensive. For large polysilicon plants, it becomes necessary to set up captive power plants to operate the reactors to produce polysilicon. This can cause a significant additional capital expense and operating cost for the polysilicon plant.

In addition, it can be seen that the above process may require large amount of water to operate the reactors during polysilicon production. Even though most of the water is re-circulated, when cooled through a cooling tower to remove the heat that is extracted, a considerable amount of water evaporates and the polysilicon plant can require replenishing the water for continuous use. Furthermore, the water has to be treated for correct mineral content and pH values, which can also significantly increase the cost of polysilicon production

### SUMMARY

A method and apparatus for low cost production of polysilicon using Siemen's reactors is disclosed. According to an aspect of the present invention, a chemical vapor deposition (CVD) reactor assembly includes a CVD reactor, a steam generator, and a steam turbine/generator. Further, the CVD reactor includes a base plate including a process gas inlet port and a process gas outlet port coupled to a process gas inlet valve and a process gas outlet valve, respectively, a reactor forming a stainless steel envelope attached to the base plate so as to form a closed stainless steel enclosure, one or more power electrodes attached to the base plate, one or more silicon rods disposed substantially in the stainless steel envelope and electrically coupled to the one or more power electrodes, and at least one heating element disposed substantially in the middle of the one or more silicon rods and coupled to the base plate.

Further, the stainless steel envelope is designed to receive a thermal fluid at room temperature and maintain a reactor wall temperature up to 450° C. For example, the thermal fluid is capable of maintaining reactor wall temperature of up to 450° C. Also, the reactor includes a thermal fluid inlet port and a thermal fluid outlet port. The at least one heating element emits radiant heat having a color temperature of at least 1800° C.

The enclosed CVD reactor assembly also includes the steam generator configured to receive the thermal fluid having a temperature of up to 450° C. from the reactor and to generate a low pressure steam around 350° C. to 450° C. upon the reactor wall reaching sufficient temperature during operation of the CVD reactor assembly. In one embodiment, the low pressure steam is used to generate electricity using low RPM (revolutions per minute) steam turbines/generators. In some embodiments, the low pressure steam is converted to super-heated steam by using an external heat source. In another embodiment, the super-heated steam is used to generate power using conventional steam turbines/generators. In one example embodiment, the enclosed CVD reactor assembly includes the steam turbine/generator configured to receive the low pressure steam/super-heated steam and to generate electricity.

Furthermore, the temperature drop in the low pressure steam/super-heated steam, which is used to operate the steam turbine/generator, manifests itself as water (i.e., condensed steam) and this condensed steam can be re-circulated back to the steam generator to exchange the heat from the thermal fluids. In addition, the thermal fluid taken out from the steam generator can be re-circulated back to the CVD reactor.

According to another aspect of the present invention, a method for production of bulk polysilicon in the CVD reactor assembly includes circulating a thermal fluid substantially around a reactor wall of the stainless steel envelope and through a steam generator to maintain the reactor wall temperature up to 450° C., evacuating the stainless steel envelope to have substantially low oxygen content, applying sufficient current using a high-voltage power supply to raise the one or more silicon rods to a firing temperature (e.g., in the range of 1000° C. to 1400° C.), applying sufficient current using a low-voltage power supply to the at least one heating element until the one or more silicon rods reach a deposition temperature (e.g., 1100° C.) of the process gas and upon a silicon reactant material reaching the firing temperature, and turning off the high-voltage power supply upon the one or more silicon rods reaching the firing temperature.

The method further includes flowing process gas (H₂) ladened with the silicon reactant material via the process gas inlet port, generating low pressure steam using the steam generator upon the reactor wall reaching sufficient temperature during operation of the CVD reactor assembly, and inputting the generated low pressure steam into a steam turbine/generator to generate electricity, depositing silicon on the one or more silicon rods to form a bulk polysilicon product, flowing gaseous byproducts of the CVD process out through the process gas outlet port, and removing the bulk polysilicon product from the closed stainless steel enclosure.

The systems and apparatuses disclosed herein may be implemented in any means for achieving various aspects. Other features will be apparent from the accompanying drawings and from the detailed description that follows.

### BRIEF DESCRIPTION OF THE DRAWINGS

Example embodiments are illustrated by way of example and not limitation in the figures of the accompanying drawings, in which like references indicate similar elements and in which:

FIG. 1 illustrates a block diagram including major components and their interconnections of a CVD reactor assembly for production of low cost polysilicon, according to an embodiment of the invention.

FIG. 2 illustrates a block diagram including major components and their interconnections of another CVD reactor assembly for production of low cost polysilicon, according to an embodiment of the invention.

FIG. 3 illustrates a block diagram including major components and their interconnections of yet another CVD reactor assembly for production of low cost polysilicon, according to an embodiment of the invention.

FIG. 4 is a process flow for production of low cost polysilicon using the CVD reactor assembly shown in FIG. 1, according to an embodiment of the invention.

FIG. 5 is another process flow for production of low cost polysilicon using a CVD reactor assembly shown in FIG. 2, according to an embodiment of the invention.

FIG. 6 is yet another process flow for production of low cost polysilicon using a CVD reactor assembly shown in FIG. 1, according to an embodiment of the invention.

Other features of the present embodiments will be apparent from the accompanying drawings and from the detailed description that follows.

### DETAILED DESCRIPTION

A method and apparatus for low cost production of polysilicon using Siemen's reactors is disclosed. In the following detailed description of the embodiments of the invention, reference is made to the accompanying drawings that form a part hereof, and in which are shown by way of illustration specific embodiments in which the invention may be practiced. These embodiments are described in sufficient detail to enable those skilled in the art to practice the invention, and it is to be understood that other embodiments may be utilized and that changes may be made without departing from the scope of the present invention. The following detailed description is, therefore, not to be taken in a limiting sense, and the scope of the present invention is defined only by the appended claims.

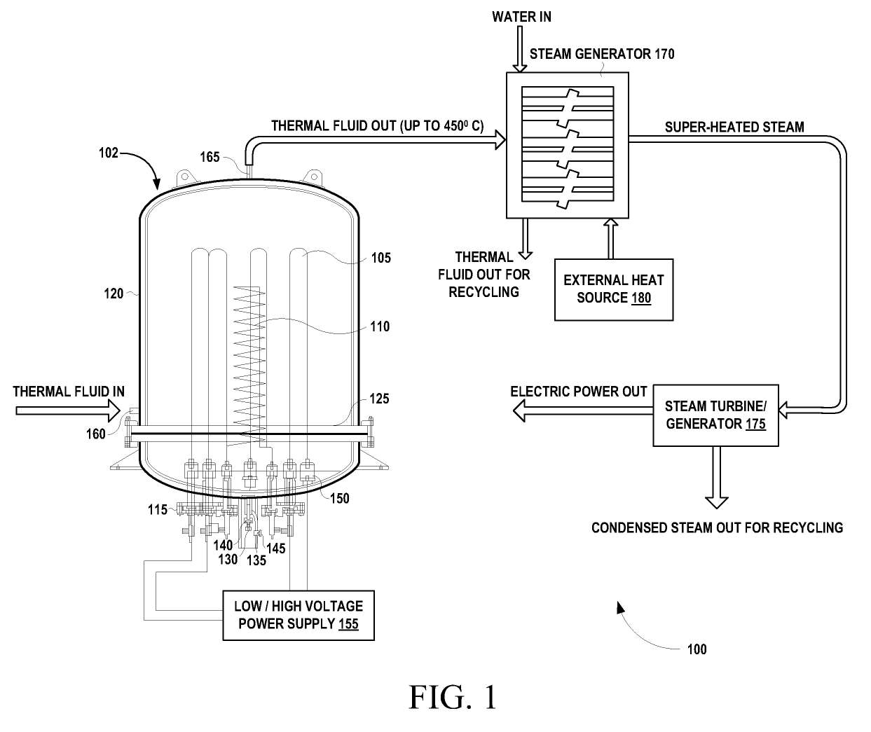

FIG. 1 illustrates a block diagram including major components and their interconnections of an enclosed chemical vapor deposition (CVD) reactor assembly 100 for production of low cost polysilicon, according to an embodiment of the invention. Particularly, FIG. 1 illustrates a CVD reactor 102 fed by a thermal fluid that is circulated through a periphery of the CVD reactor 102 to remove heat generated through the polysilicon production process.

As shown in FIG. 1, the enclosed CVD reactor assembly 100 includes the CVD reactor 102, a steam generator 170 and a steam turbine/generator 175. Further as shown in FIG. 1, the CVD reactor 102 includes one or more silicon rods 105, a heating element 110, one or more power electrodes 115, a reactor 120, a base plate 125, a process gas inlet port 130 and a process gas outlet port 135, a process gas inlet valve 140 and a process gas outlet valve 145, one or more graphite support assemblies 150, and a high/low voltage power supply 155. Further, the reactor 120 includes a thermal fluid inlet port 160 and a thermal fluid outlet port 165 as shown in FIG. 1. In one example embodiment, the reactor 120 includes a double walled chamber.

Moreover as shown in FIG. 1, the base plate 125 includes the process gas inlet port 130 and the process gas outlet port 135 coupled to the process gas inlet valve 140 and the process gas outlet valve 145, respectively. Further, the reactor 120 forms a stainless steel envelope attached to the base plate 125 so as to form a closed stainless steel enclosure. The stainless steel envelope is designed to receive a thermal fluid at room temperature via the thermal fluid inlet port 160 and maintain a reactor wall temperature up to 450° C. In one example embodiment, the thermal fluid is capable of maintaining reactor wall temperature of up to 450° C. Also, the stainless steel envelope sends the thermal fluid having a temperature of up to 450° C. to the steam generator 170 via the thermal fluid outlet port 165 upon the reactor wall reaching sufficient temperature during operation of the CVD reactor assembly 100.

In one embodiment, the steam generator 170 is configured to receive the thermal fluid having the temperature of up to 450° C. from the reactor 120 and to generate a low pressure steam around 350° C. to 450° C. In one embodiment, the low pressure steam is used to generate electricity using low RPM (revolutions per minute) steam turbines or low pressure steam turbines/generators, such as the steam turbine/generator 175 shown in FIG. 1. In some embodiments, the low pressure steam is converted to super-heated steam by using an external heat source 180. In one embodiment, the super-heated steam is used to generate power using conventional steam turbines/generators. The enclosed CVD reactor assembly 100 further includes the steam turbine/generator 175 configured to receive the low pressure steam/super-heated steam and to generate electricity.

As shown in FIG. 1, the CVD reactor 102 also includes the one or more power electrodes 115 attached to the base plate 125. The CVD reactor 102 further includes the one or more silicon rods 105 disposed substantially in the stainless steel envelope. In one example embodiment, the silicon rods 105 are disposed substantially vertically in the stainless steel envelope. Further, the silicon rods 105 are electrically coupled to the one or more power electrodes 115.

Also, the CVD reactor 102 includes the heating element 110 disposed substantially in the middle of the silicon rods 105. As shown in FIG. 1, the heating element 110 is disposed substantially vertically in the middle of the one or more silicon rods 105. In some embodiments, the heating element 110 is coupled to the base plate 125. Further, the heating element 110 emits radiant heat having a color temperature of at least 1800° C.

In one example embodiment, the heating element 110 is a thin filament made from high purity tungsten, tantalum, molybdenum, or silicon carbide. Further, the thin filament is coated with a substantially thin layer of silicon to prevent any exposure of element to process gases. In these embodiments, the process gas is hydrogen (H₂). Further, the thin filament is coupled to the power electrodes 115 that supply power. For example, the thin filament is disposed in spiral, elliptical, rectangular, square shapes and the like.

Further as shown in FIG. 1, the CVD reactor 102 includes one or more graphite support assemblies 150 substantially disposed onto the one or more power electrodes 115 to support the one or more silicon rods 105 and the heating element 110. As illustrated in FIG. 1, the enclosed CVD reactor assembly 100 also includes the high/low-voltage power supply 155 coupled to the heating element 110.

In operation, the heating element 110 is used for heating the silicon rods 105 during startup, in the CVD reactor 102. In these embodiments, the heating element 110 is configured to be disposed substantially in the middle of the silicon rods 105. For example, the heating element 110 emits radiant heat having a color temperature of approximately 1800° C. Further, the thermal fluid is circulated substantially around a reactor wall of the stainless steel envelope and through the steam generator 170 to maintain the reactor wall temperature up to 450° C.

Further in operation, current sufficient for raising the silicon rods 105 to a firing temperature is applied to the heating element 110 using the high voltage power supply (e.g., the high/low voltage power supply 155). In one example embodiment, the firing temperature is in the range of about 1000° C. to 1400° C. Further, the low-voltage power supply (e.g., the high/low voltage power supply 155) applies sufficient current to the heating element 110 until the silicon rods 105 reach a deposition temperature of the process gas and upon a silicon reactant material reaching the firing temperature. In one example embodiment, the deposition temperate is about 1100° C. In one embodiment, the high voltage power supply is turned off upon the one or more silicon rods 105 reaching the firing temperature.

As shown in FIG. 1, the steam generator 170 generates low pressure steam using the thermal fluid received from the thermal fluid outlet port 165 of the reactor 120. In another embodiment, the generated low pressure steam is inputted into the low pressure steam turbine/generator 175 to generate electricity. In some embodiments, the low pressure steam is converted to super-heated steam by using the external heat source 180. The enclosed CVD reactor assembly 100 further includes the steam turbine/generator 175 configured to receive the low pressure steam/super-heated steam and to generate electricity. In one example embodiment, power is supplied to an electrical grid using the generated electricity.

Furthermore, the temperature drop in the low pressure steam/super-heated steam, which is used to operate the steam turbine/generator 175, manifests itself as water (i.e., condensed steam) and this condensed steam can be re-circulated back to the steam generator 170 to exchange the heat from the thermal fluids. In addition, the thermal fluid taken out from the steam generator 170 can be re-circulated back to the CVD reactor 102.

Further in operation, the process gas (i.e., H₂) ladened with the silicon reactant material is flown through the process gas inlet port 130 coupled to the process gas inlet valve 140. In these embodiments, the gaseous byproducts obtained during the CVD process are flown out through the process gas outlet port 135. Finally, the bulk polysilicon product obtained during the CVD process in the CVD reactor 102 is removed from the closed stainless steel enclosure.

In the example embodiment illustrated in FIG. 1, the CVD reactor 102 for the production of the bulk polysilicon uses the thermal fluid as the cooling media, for cooling the walls of the CVD reactor 102. In one embodiment, the temperature of the thermal fluid entering the reactor wall through the thermal fluid inlet port 160 is maintained at around 30° C. and the outlet thermal fluid is extracted at the temperature of up to 450° C. from the reactor wall. It can be noted that the temperature of the reactor walls (e.g., inner walls) is maintained at 450° C. or less to prevent silicon depositing on the reactor walls.

In another embodiment, the hot thermal fluid (e.g., up to 450° C.) that is removed from the reactor 120 is sent to the steam generator 170 where heat from the thermal fluid is exchanged with the water to raise the water temperature from 30° C. to a low pressure steam temperature of 350° C. to 450° C. Further, the low pressure steam is converted to super-heated steam by using heat from the external source 180 and various hot gasses generated during production of bulk polysilicon. The generated low pressure steam/super-heated steam is then sent to the steam turbine/generator 175 which converts the low pressure steam/super-heated steam to electric power. As shown in FIG. 1, the thermal fluid taken out from the steam generator 170 is re-circulated back to the CVD reactor 102 and the condensed steam taken out from the steam turbine/generator 175 is re-circulated back to the steam generator 170.

For example, a typical 250 MT capacity reactor can require about 3500 KWh/hr of energy. Assuming that about 60% of the heat from the reactor is removed using the thermal fluid, one skilled in the art can understand that, about 2000 kWh/hr of energy is removed from the reactor. This is during normal operation of the reactor. In one example embodiment, by maintaining heat at 400° C., lesser amount of heat is being removed from the reactor walls since the radiation loss will be considerably less. This results in using significantly lesser power for running the CVD reactor 102. The above mentioned process can be used to reactor of any size and energy extracted depending on the design of the reactor.

Further, each reactor can be running for about 100 to 180 hours per batch, depending upon the efficiency of the process, the types of gases used, and so on. It can be seen that nearly 300 MWh of energy can be produced for each cycle, assuming an average of 150 hour process time for each reactor.

Further, the power produced at the steam turbine/generator 175 depends on the generated steam temperature. Generally, for low power generation, approximately 22 tons of low pressure steam is required to produce about 5 MW of power. Obtaining 22 tons of low pressure steam is an attractive proposition for large polysilicon plants, operating with a number of reactors. Further, the heat output from several reactor banks can be tied together to the steam generator 170 and to the steam turbine/generator 175 to produce additional power. Further, the additional power produced by the steam turbine/generator 175 can be fed back to the grid to significantly lower the cost of production of polysilicon. The above process can result in savings of at least 60% in the energy cost, which can reduce the cost of producing polysilicon by at least 20%.

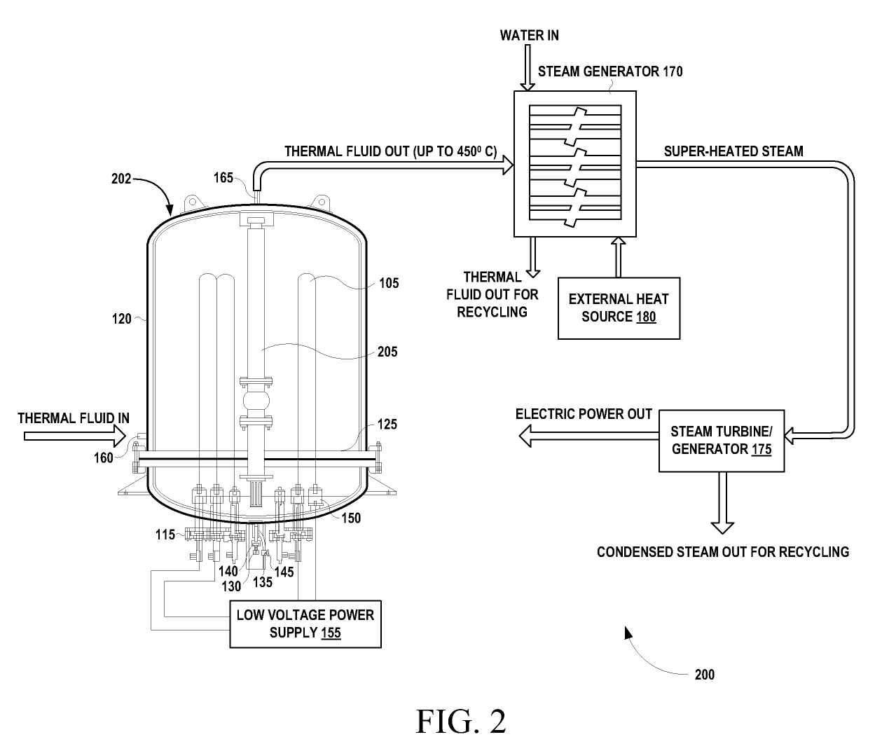

FIG. 2 illustrates another block diagram including major components and there interconnections of an enclosed CVD reactor assembly 200 for production of low cost polysilicon, according to an embodiment of the invention.

As shown in FIG. 2, the enclosed CVD reactor assembly 200 includes a CVD reactor 202, the steam generator 170, and the steam turbine/generator 175. Further, the CVD reactor 202 includes the one or more silicon rods 105, the one or more power electrodes 115, the reactor 120, the base plate 125, the process gas inlet port 130 and the process gas outlet port 135, the process gas inlet valve 140 and the process gas outlet valve 145, the one or more graphite support assemblies 150, the high/low-voltage power supply 155, and a heat radiation system 205. Further, the reactor 120 includes the thermal fluid inlet port 160 and the thermal fluid outlet port 165 as shown in FIG. 1. In one example embodiment, the reactor 120 is a double walled chamber.

Further as shown in FIG. 2, the CVD reactor 202 includes the base plate 125 including the process gas inlet port 130 and the process gas outlet port 135 coupled to the process gas inlet valve 140 and the process gas outlet valve 145. The CVD reactor 202 also includes the reactor 120 forming a stainless steel envelope attached to the base plate 125.

In one example embodiment, the stainless steel envelope is designed to receive the thermal fluid at room temperature (e.g., through the thermal fluid inlet port 160) and maintain a reactor wall temperature up to 450° C. The thermal fluid having a temperature of up to 450° C. is extracted from the reactor 120 upon the reactor wall reaching sufficient temperature during operation of the CVD reactor assembly 200 and sent to the steam generator 170 to generate low pressure steam. In one embodiment, the steam generator 170 is configured to receive the thermal fluid having the temperature of up to 450° C. from the reactor 120 and to generate the low pressure steam around 350° C. to 450° C. In one embodiment, the low pressure steam turbine/generator 175 is used to convert the low pressure steam into electric power. In some embodiments, the low pressure steam is converted to super-heated steam by using heat from the external source 180 and various hot gasses generated during the production of bulk polysilicon. In one embodiment, the super-heated steam is used to generate power using conventional steam turbine/generators. Further, the steam turbine/generator 175 is configured to receive the generated low pressure steam/super-heated steam and to convert the low pressure steam/super-heated steam to electric power.

The CVD reactor 202 further includes the one or more power electrodes 115 attached to the base plate 125. Also, the CVD reactor 202 includes one or more silicon rods 105 disposed substantially in the stainless steel envelope and electrically coupled to the one or more power electrodes 115. In addition, the CVD reactor 202 includes the heat radiation system 205 that is annularly disposed in the reactor 120 having at least one heating element which emits thermal radiation having a color temperature of at least 2000° C.

In operation, the heat radiation system 205 irradiates the silicon rods 105 with thermal radiation having a color temperature of at least 2000° C. The radiant heat is applied using the at least one heating element to the closed stainless steel enclosure sufficient for raising the one or more silicon rods 105 to a firing temperature. The irradiation is terminated when a particular electrical voltage applied to the silicon rods 105 causes a specified current to flow. The method of production of bulk polysilicon is similar to the method illustrated in FIG. 1.

In the example embodiment illustrated in FIG. 2, the thermal fluid at room temperature (30° C.) is circulated through the periphery of the reactor wall of the closed stainless steel enclosure through the thermal fluid inlet port 160. The thermal fluid takes away the heat generated on the reactor wall by the hot silicon rods 105. Since the thermal fluid has a high vapor pressure at high temperatures there is very little loss of the thermal fluid to the atmosphere. Also, the thermal fluids can be operated in a closed loop mode.

The thermal fluid at the thermal fluid outlet port 165 of the reactor wall, which typically is around 400° C., is inputted to the steam generator 170. The steam generator 170 exchanges the heat from the thermal fluid (e.g., up to 450° C.) to raise the water temperature from 30° C. to the low pressure steam temperature of 350° C. to 450° C.

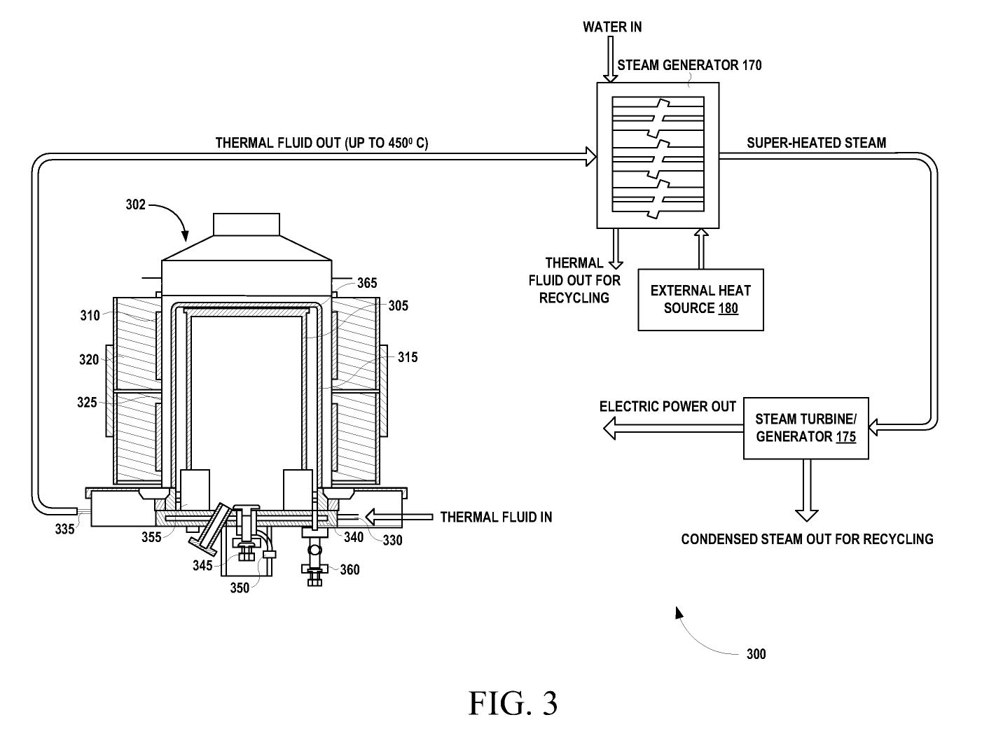

Further, the low pressure steam is converted to super-heated steam by using the external heat source 180 and various hot gasses generated during the production of bulk polysilicon. Further, the low pressure steam/super-heated steam is then sent to the steam turbine/generator 175 where energy supplied by the low pressure steam/super-heated steam operates the steam turbine/generator 175 to produce electricity. As shown in FIG. 2, the thermal fluid taken out from the steam generator 170 is re-circulated back to the CVD reactor 102. Also, the temperature drop in the low pressure steam/super-heated steam, which is used to operate the steam turbine/generator 175, manifests itself as water (i.e., condensed steam) and this condensed steam can be re-circulated back to the steam generator 170 to exchange the heat from the thermal fluids. The above mentioned process for cooling the reactor walls can also be applied to other types of CVD reactors, such as those illustrated in FIG. 3.

FIG. 3 illustrates a block diagram including major components and their interconnections of another enclosed CVD reactor assembly 300 for production of low cost polysilicon, according to an embodiment of the present invention. It can be seen from FIG. 3 that, the major components and their interconnections of the enclosed CVD reactor assembly 300 are similar to the enclosed CVD reactor assembly 100 and 200 of FIG. 1 and FIG. 2, respectively, except a CVD reactor 302 of a different type is used in FIG. 3. Further, FIG. 3 depicts a side elevation cut-away view of an exemplary CVD reactor (i.e., the CVD reactor 302), configured with a single silicon tube 305 deposition target for accumulating an interior surface deposit of polysilicon.

Particularly, FIG. 3 illustrates the CVD reactor 302, the steam generator 170, and the steam turbine/generator 175. As shown in FIG. 3, the CVD reactor 302 includes the silicon tube 305, an electric heater assembly 310, a quartz envelope 315, an insulation layer 320, a quartz heater cover 325, a thermal fluid inlet port 330, a thermal fluid outlet port 335, a base plate 340, a process gas inlet 345, a process gas outlet 350, a graphite support 355 and a blanket gas inlet 360, according to one embodiment.

In operation, radiant heat is applied by the electric heater assembly 310 until the silicon tube 305 reaches the deposition temperature. Further, radiant heat penetrates through quartz envelope 315 to the silicon tube 305. When the silicon tube 305 reaches the deposition temperature, a process gas is fed into the CVD reactor 302 through the process gas inlet 345.

Further in operation, a thermal fluid around 30° C. is circulated around the base plate 340 and also around any other metal part of the CVD reactor that is exposed to the heat through the thermal fluid inlet port 330 and the thermal fluid around 450° C. is extracted at the thermal fluid outlet port 335. In one example embodiment, the thermal fluid is capable of maintaining reactor wall temperature of up to 450° C. Further, the thermal fluid extracted from the quartz envelope 315 is sent to the steam generator 170 to generate low pressure steam which is fed to the low pressure steam turbine/generator 175.

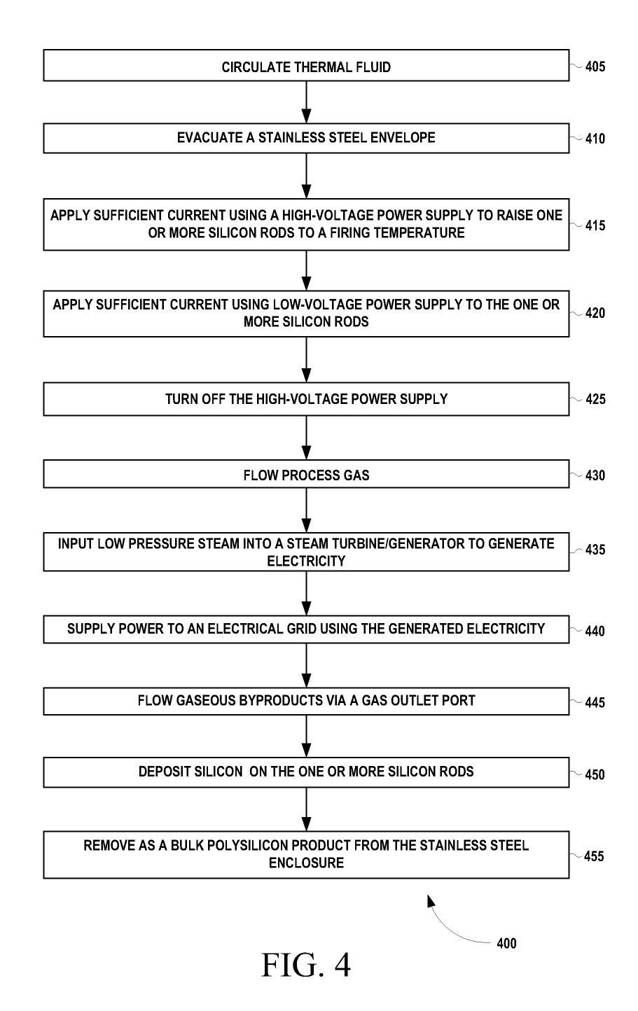

FIG. 4 is a process flow 400 for production of low cost polysilicon using the enclosed CVD reactor assembly 100 shown in FIG. 1, according to an embodiment of the invention. In step 405, a thermal fluid is initially circulated substantially around a reactor wall of a stainless steel envelope and through a steam generator 170. In these embodiments, a reactor 120 attached to a base plate 125, forms the stainless steel envelope. In some embodiments, the thermal fluid is capable of maintaining reactor wall temperature of up to 450° C.

In step 410, the stainless steel envelope is evacuated to have substantially low oxygen content. In step 415, sufficient current is applied using a high-voltage power supply (e.g., the high/low voltage power supply 155 of FIG. 1) to raise one or more silicon rods 105 to a firing temperature.

In step 420, the sufficient current is applied using a low-voltage power supply (e.g., the high/low voltage power supply 155 of FIG. 1) to the at least one heating element until the one or more silicon rods 105 reach a deposition temperature of the process gas and upon a silicon reactant material reaching the firing temperature. In step 425, the high-voltage power supply is turned off upon the one or more silicon rods 105 reaching the firing temperature.

In step 430, a process gas (e.g., Hydrogen (H₂)) ladened with the silicon reactant material is flown via a process gas inlet port 130. For example, the silicon reactant material includes silane, trichlorosilane, dichlorosilane or silicon tetrachloride. In one example embodiment, the steam generator 170 generates low pressure steam using the thermal fluid extracted from the reactor wall upon the reactor wall reaching sufficient temperature during operation of the CVD reactor assembly. In another example embodiment, various hot gasses generated during production of bulk polysilicon are inputted into the steam generator 170 to generate the low pressure steam. In step 435, the generated low pressure steam is inputted into a low pressure steam turbine/generator 175 to generate electricity. In step 440, power is supplied to an electrical grid using the generated electricity.

In step 445, gaseous byproducts of the CVD process are flown out through the process gas outlet port 135. In step 450, silicon is deposited on the one or more silicon rods 105 to form a bulk polysilicon product. In step 455, the bulk polysilicon product is removed from the closed stainless steel enclosure.

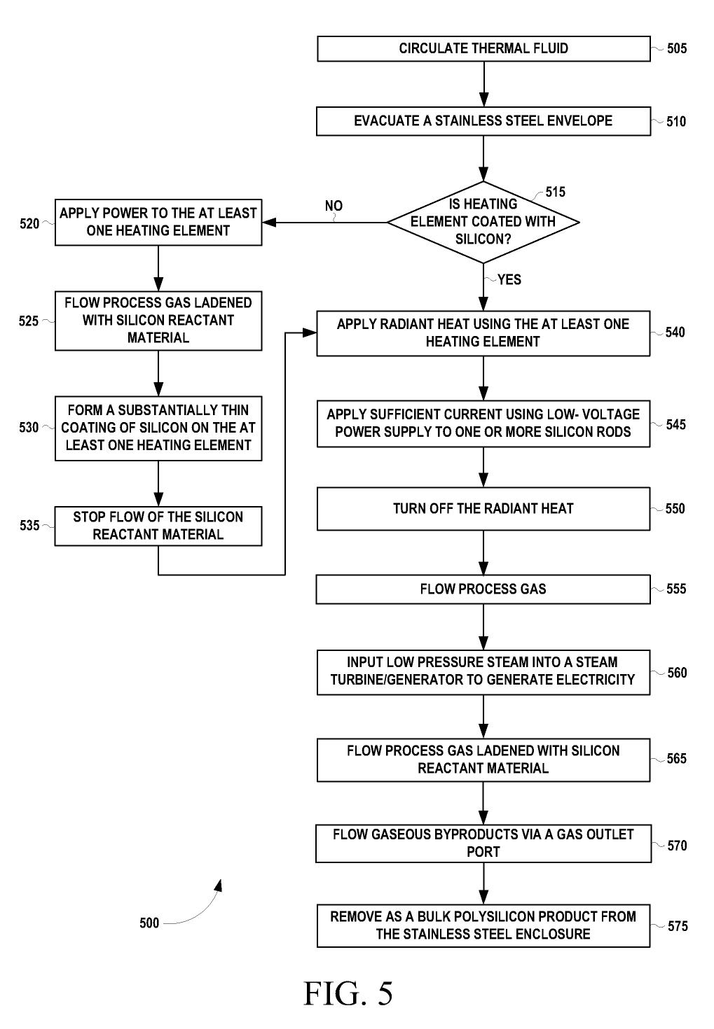

FIG. 5 is another process flow 500 for production of low cost polysilicon using the enclosed CVD reactor assembly 200 shown in FIG. 2, according to an embodiment of the invention. In step 505, a thermal fluid is circulated substantially around a reactor wall of the stainless steel envelope and through a steam generator 170 to maintain a reactor wall temperature up to 450° C. In one example embodiment, the thermal fluid is capable of maintaining reactor wall temperature of up to 450° C. In step 510, a stainless steel envelope is evacuated to have substantially low oxygen content. In step 515, a check is made to determine whether at least one heating element 110 is coated with silicon.

If the heating element 110 is not coated with silicon, then the steps 520 to 535 are performed for coating the heating element 110 with silicon. In step 520, sufficient current is applied (e.g., using a power supply) to the heating element 110 of the closed stainless steel enclosure, sufficient for raising the heating element 110 to a deposition temperature. In one example embodiment, the deposition temperate is about 1100° C. In step 525, a process gas ladened with a silicon reactant material is flown via a process gas inlet port 130. In some embodiments, the process gas is H₂ and the silicon reactant material is silane, trichlorosilane, dichlorosilane, silicon tetrachloride, etc.

In step 530, a substantially thin coating of silicon, sufficient to prevent metal exposure on the heating element 110 is formed. In step 535, flow of the silicon reactant material is stopped upon forming the substantially thin coating of silicon, sufficient to prevent the metal exposure on the heating element 110.

In step 515, if the heating element 110 is coated with silicon, then step 540 is performed directly without performing the steps 520 to 535. The process 500 goes to the step 540 either from step 515 or from step 535, based on the determination made in step 515.

In step 540, radiant heat using the at least one heating element (e.g., through the heat radiation system 205 of FIG. 2) is applied to the closed stainless steel enclosure sufficient for raising one or more silicon rods 105 to a firing temperature. In one example embodiment, the firing temperature is in the range of about 1000° C. to 1400° C. In step 545, sufficient current using low-voltage power supply 155 (e.g., as shown in FIG. 2) is applied to the at least one heating element until the one or more silicon rods 105 reach a deposition temperature of the process gas and upon the silicon reactant material reaching the firing temperature. In step 550, the radiant heat is turned off upon the silicon rods 105 reaching the firing temperature. In step 555, process gas (e.g., H₂) ladened with a silicon reactant material is flown via the process gas inlet port 130. In one example embodiment, the steam generator 170 generates low pressure steam using the thermal fluid extracted from the reactor wall upon the reactor wall reaching sufficient temperature during operation of the CVD reactor assembly. In another example embodiment, various hot gasses generated during the production of bulk polysilicon are inputted into the steam generator 170 to generate low pressure steam. Further, the steam

In step 565, process gas ladened with silicon reactant material is flown via the process gas inlet port 130. In step 570, gaseous byproducts of the CVD process are flown out through a process gas outlet port 135. In step 575, the bulk polysilicon product is removed from the closed stainless steel enclosure. In one example embodiment, silicon is deposited on the one or more silicon rods 105 to form a bulk polysilicon product.

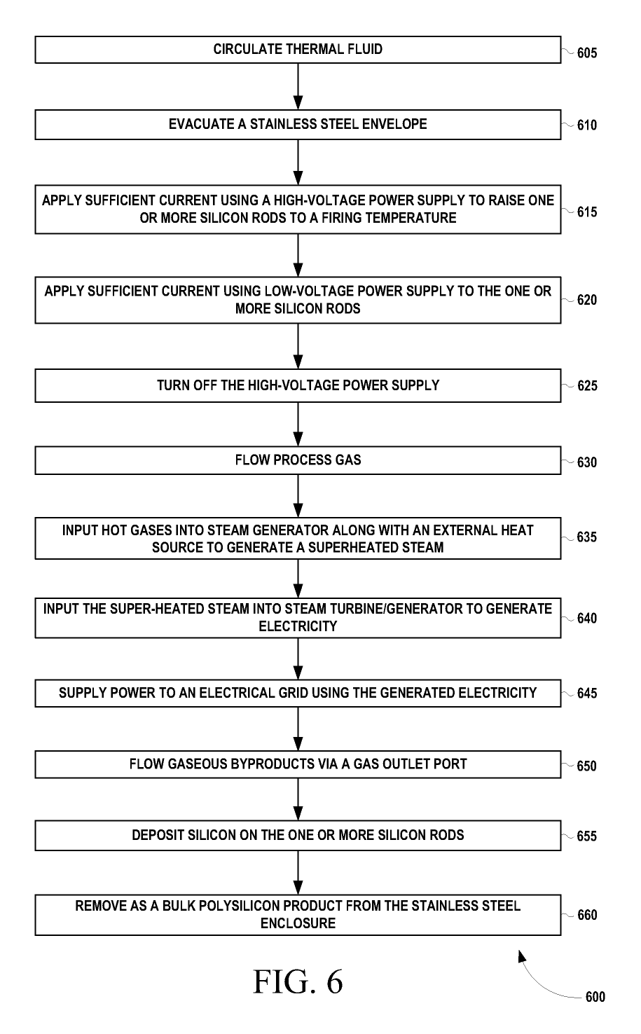

FIG. 6 is yet another process flow 600 for production of low cost polysilicon using an enclosed CVD reactor assembly 100 shown in FIG. 1, according to an embodiment of the invention. In step 605, a thermal fluid is circulated substantially around a reactor wall of a stainless steel envelope and through a steam generator 170 to maintain the reactor wall temperature up to 450° C. In one example embodiment, low pressure steam is generated using the steam generator 170 upon the reactor wall reaching sufficient temperature during operation of the CVD reactor assembly 100. In step 610, the stainless steel envelope is evacuated to have substantially low oxygen content.

In step 615, sufficient current is applied using a high-voltage power supply (e.g., low/high voltage power supply 155 of FIG. 1) to raise one or more silicon rods 105 to a firing temperature. In step 620, sufficient current is applied using a low-voltage power supply (e.g., low/high voltage power supply 155 of FIG. 1) to at least one heating element 110 until the one or more silicon rods 105 reach a deposition temperature of a process gas and upon a silicon reactant material reaching the firing temperature.

In step 625, the high-voltage power supply is turned off upon the one or more silicon rods 105 reaching the firing temperature. In step 630, the process gas ladened with the silicon reactant material is flown via the process gas inlet port 130. In step 635, various hot gasses generated during production of bulk polysilicon are inputted along with an external heat source 180 into the steam generator 170 to generate super heated steam. In step 640, the generated super heated steam is inputted into a steam turbine/generator 175 to generate electricity.

In step 645, power is supplied to an electrical grid using the generated electricity. In step 650, gaseous byproducts of the CVD process are flown out through the process gas outlet port 135. In step 655, silicon is deposited on the one or more silicon rods 105 to form a bulk polysilicon product. In step 660, the bulk polysilicon product is removed from the closed stainless steel enclosure.

The above described method generates power from polysilicon reactors during production of polysilicon using the Siemen's process. The above described method also saves water that is lost by evaporation to the atmosphere at the cooling tower. Currently, power is similarly generated in nuclear reactors. However, the operating temperatures in nuclear reactors are significantly higher and the fluids used for heat exchange are different. Further, the operating pressure is also high. In the above described process, the operating temperature is not very high and hence the operating pressures are low and much more stream is required to generate the steam for power generation.

Generally, polysilicon production is a batch process and therefore a number of reactors can be coupled together and their outputs are sent to a single steam generator and a steam turbine/generator. In one example embodiment, a plant operating with about 50 reactors can have 10 reactors coupled together to each steam generator and a steam turbine/generator. In this case, 5 steam turbine/generators can be coupled to a common grid.

Further, the polysilicon plant will have a number of other types of reactors for producing various gases which are used in the polysilicon reactors. It can be seen that all the heat generated in the plant can be diverted to these steam generators to produce more power, thereby, significantly reducing the auxiliary power load for the entire plant.

Although the present embodiments have been described with reference to specific example embodiments, it will be evident that various modifications and changes may be made to these embodiments without departing from the broader spirit and scope of the various embodiments. For example, the various devices, modules, analyzers, generators, etc. described herein may be enabled and operated using hardware circuitry (e.g., CMOS based logic circuitry), firmware, software and/or any combination of hardware, firmware, and/or software (e.g., embodied in a machine readable medium).

What is claimed is:

1. An enclosed chemical vapor deposition (CVD) reactor, comprising:
a base plate including a process gas inlet and outlet ports coupled to process gas inlet and outlet valves, respectively;
a reactor forming a stainless steel envelope attached to the base plate and wherein the stainless steel envelope is designed to receive a thermal fluid at room temperature and maintain a reactor wall temperature up to 450° C. and wherein the reactor having a thermal fluid inlet port and a thermal fluid outlet port;
one or more power electrodes attached to the base plate;
one or more silicon rods disposed substantially in the stainless steel envelope and electrically coupled to the one or more power electrodes; and
a heat radiation system that is annularly disposed in the reactor having at least one heating element which emits thermal radiation having a color temperature of at least 2000° C.

2. The enclosed CVD reactor of claim 1, wherein the reactor comprises a double walled chamber.

3. The enclosed CVD rector of claim 1, wherein the thermal fluid is capable of maintaining reactor wall temperature of up to 450° C.

4. An enclosed chemical vapor deposition (CVD) reactor assembly, comprising:
a CVD reactor, comprising:
a base plate including a process gas inlet and outlet ports coupled to process gas inlet and outlet valves, respectively;
a reactor forming a stainless steel envelope attached to the base plate and wherein the stainless steel envelope is designed to receive a thermal fluid at room temperature and maintain a reactor wall temperature up to 450° C. and wherein the reactor having a thermal fluid inlet port and a thermal fluid outlet port;
one or more power electrodes attached to the base plate;
one or more silicon rods disposed substantially in the stainless steel envelope and electrically coupled to the one or more power electrodes; and
a heat radiation system that is annularly disposed in the reactor having at least one heating element which emits thermal radiation having a color temperature of at least 2000° C.;
a steam generator configured to receive the thermal fluid having a temperature of up to 450° C. from the reactor and generate a low pressure steam around 350° C. to 450° C.; and
a low pressure steam turbine/generator configured to receive the low pressure steam around 350° C. to 450° C. and generate electricity.

5. The enclosed CVD reactor assembly of claim 4, wherein the reactor comprises a double walled chamber.

6. The enclosed CVD rector assembly of claim 4, wherein the thermal fluid is capable of maintaining reactor wall temperature of up to 450° C.

7. An enclosed CVD reactor assembly, comprising:
a CVD reactor, comprising:
a base plate including a process gas inlet and outlet ports coupled to process gas inlet and outlet valves;
a reactor forming a stainless steel envelope attached to the base plate and wherein the stainless steel envelope is designed to receive a thermal fluid at room temperature and maintain a reactor wall temperature up to 450° C. and wherein the reactor having a thermal fluid inlet port and a thermal fluid outlet port;
one or more power electrodes attached to the base plate;
one or more silicon rods disposed substantially in the stainless steel envelope and electrically coupled to the one or more power electrodes; and
at least one heating element is disposed substantially in the middle of the one or more silicon rods and coupled to the base plate and wherein the at least one heating element emits radiant heat having a color temperature of at least 1800° C.;
a steam generator configured to receive the thermal fluid having a temperature of up to 450° C. from the reactor and generate a low pressure steam around 350° C. to 450° C.; and
a low pressure steam turbine/generator configured to receive the low pressure steam around 350° C. to 450° C. and generate electricity.

8. The enclosed CVD reactor assembly of claim 7, wherein the reactor comprises a double walled chamber.

9. The enclosed CVD rector assembly of claim 7, wherein the thermal fluid the thermal fluid is capable of maintaining reactor wall temperature of up to 450° C.

10. The enclosed CVD reactor assembly of claim 7, where in the at least one heating element is a thin filament made from materials selected from the group consisting of tungsten, tantalum, molybdenum, and silicon carbide that emit radiant heat having a color temperature of about 1300° C.

11. The enclosed CVD reactor assembly of claim 10, wherein the thin filament is coated with a substantially thin layer of silicon to prevent any exposure of metal to process gases.

12. The enclosed CVD reactor assembly of claim 7, further comprising:
a low-voltage power supply coupled to the at least one heating element.

13. A method for production of bulk polysilicon in a CVD reactor assembly, wherein the CVD reactor assembly includes a base plate having a process gas inlet and outlet ports, a reactor forming a stainless steel envelope attached to the base plate so as to form a closed stainless steel enclosure, a process gas inlet and outlet valves coupled to the process gas inlet and outlet ports, respectively, one or more power electrodes attached to the base plate, and at least one heating element disposed substantially around one or more silicon rods, comprising:
circulating a thermal fluid substantially around a reactor wall of the stainless steel envelope and through a steam generator to maintain the reactor wall temperature up to 450° C. and generating low pressure steam using the steam generator upon the reactor wall reaching sufficient temperature during operation of the CVD reactor assembly;
evacuating the stainless steel envelope to have substantially low oxygen content;
determining whether the at least one heating element is coated with silicon;
if so, applying radiant heat using the at least one heating element to the closed stainless steel enclosure sufficient for raising the one or more silicon rods to a firing temperature;
applying sufficient current using low-voltage power supply to the at least one heating element until the one or more silicon rods reach a deposition temperature of a process gas and upon a silicon reactant material reaching the firing temperature;
turning off the radiant heat upon the one or more silicon rods reaching the firing temperature;
inputting the generated low pressure steam into a low pressure steam turbine/generator to generate electricity;
flowing the process gas ladened with the silicon reactant material via the process gas inlet port;
depositing silicon on the one or more silicon rods to form a bulk polysilicon product;
flowing gaseous byproducts of the CVD process out through the process gas outlet port; and
removing the bulk polysilicon product from the closed stainless steel enclosure.

14. The method of claim 13, further comprising:
supplying power to an electrical grid using the generated electricity.

15. The method of claim 13, further comprising:
inputting various hot gasses generated during the production of bulk polysilicon into the steam generator to generate low pressure steam.

16. The method of claim 13, further comprising:
if not, applying sufficient current using a power supply to at least one heating element to the closed stainless steel enclosure sufficient for raising the at least one heating element to the deposition temperature;
flowing the process gas ladened with a silicon reactant material via the process gas inlet port;
forming a substantially thin coating of silicon sufficient to prevent metal exposure on the at least one heating element; and
stop flowing of the silicon reactant material.

17. The method of claim 16, wherein, in applying the radiant heat using the at least one heating element to the closed stainless steel enclosure sufficient for raising the at least one heating element to the deposition temperature, the deposition temperate is about 110° C.

18. The method of claim 16, wherein, in applying sufficient current using low-voltage power supply until the one or more silicon rods reach the deposition temperature of the process gas and upon the silicon reactant material reaching the firing temperature, the firing temperature is in the range of about 1000° C. to 1400° C.

19. The method of claim 16, wherein the process gas is Hydrogen (H₂).

20. The method of claim 16, wherein the silicon reactant material is selected from the group consisting of silane, trichlorosilane, dichlorosilane and silicon tetrachloride.

21. A method for production of bulk polysilicon in a CVD reactor assembly, wherein the CVD reactor assembly includes a base plate having a process gas inlet and outlet ports, a reactor forming a stainless steel envelope attached to the base plate so as to form a closed stainless steel enclosure, a process gas inlet and outlet valve coupled to the process gas inlet and outlet ports, one or more power electrodes attached to the base plate, and one or more silicon rods electrically coupled to the one or more power electrodes comprising:
circulating a thermal fluid substantially around a reactor wall of the stainless steel envelope and through a steam generator to maintain the reactor wall temperature up to 450° C. and generating low pressure steam using the steam generator upon the reactor wall reaching sufficient temperature during operation of the CVD reactor assembly;
evacuating the stainless steel envelope to have substantially low oxygen content;
applying sufficient current using a high-voltage power supply to raise the one or more silicon rods to a firing temperature;
applying sufficient current using a low-voltage power supply to the at least one heating element until the one or more silicon rods reach a deposition temperature of a process gas and upon a silicon reactant material reaching the firing temperature;
turning off the high-voltage power supply upon the one or more silicon rods reaching the firing temperature;
flowing the process gas ladened with the silicon reactant material via the process gas inlet port;
inputting the generated low pressure steam into a low pressure steam turbine/generator to generate electricity;
flowing gaseous byproducts of the CVD process out through the process gas outlet port;
depositing silicon on the one or more silicon rods to form a bulk polysilicon product; and
removing the bulk polysilicon product from the closed stainless steel enclosure.

22. The method of claim 21, further comprising:
supplying power to an electrical grid using the generated electricity.

23. The method of claim 21, further comprising:
inputting various hot gasses generated during production of bulk polysilicon into the steam generator to generate low pressure steam.

24. The method of claim 21, wherein the process gas is Hydrogen (H₂).

25. The method of claim 21, wherein the silicon reactant material is selected from the group consisting of silane, trichlorosilane, dichlorosilane and silicon tetrachloride.

26. A method for production of bulk polysilicon in a CVD reactor assembly, wherein the CVD reactor assembly includes a base plate having a process gas inlet and outlet ports, a reactor forming a stainless steel envelope attached to the base plate so as to form a closed stainless steel enclosure, a process gas inlet and outlet valve coupled to the process gas inlet and outlet ports, one or more power electrodes attached to the base plate, and one or more silicon rods electrically coupled to the one or more power electrodes comprising:
circulating a thermal fluid substantially around a reactor wall of the stainless steel envelope and through a steam generator to maintain the reactor wall temperature up to 450° C. and generating low pressure steam using the steam generator upon the reactor wall reaching sufficient temperature during operation of the CVD reactor assembly;
evacuating the stainless steel envelope to have substantially low oxygen content;
applying sufficient current using a high-voltage power supply to raise the one or more silicon rods to a firing temperature;
applying sufficient current using a low-voltage power supply to the at least one heating element until the one or more silicon rods reach a deposition temperature of a process gas and upon a silicon reactant material reaching the firing temperature;
turning off the high-voltage power supply upon the one or more silicon rods reaching the firing temperature;
flowing the process gas ladened with the silicon reactant material via the process gas inlet port;
inputting various hot gasses generated during production of bulk polysilicon along with an external heat source into the steam generator to generate super heated steam;
inputting the generated super heated steam into a steam turbine/generator to generate electricity;
flowing gaseous byproducts of the CVD process out through the process gas outlet port;
depositing silicon on the one or more silicon rods to form a bulk polysilicon product; and
removing the bulk polysilicon product from the closed stainless steel enclosure.

27. The method of claim 26, further comprising:
supplying power to an electrical grid using the generated electricity.

28. The method of claim 26, wherein the process gas is Hydrogen (H₂).

29. The method of claim 26, wherein the silicon reactant material is selected from the group consisting of silane, trichlorosilane, dichlorosilane and silicon tetrachloride.

30. An enclosed chemical vapor deposition (CVD) reactor assembly, comprising:
a CVD reactor, comprising:
a base plate including a process gas inlet and outlet ports coupled to process gas inlet and outlet valves, respectively;
a reactor forming a stainless steel envelope attached to the base plate and wherein the stainless steel envelope is designed to receive a thermal fluid at room temperature and maintain a reactor wall temperature up to 450° C. and wherein the reactor having a thermal fluid inlet port and a thermal fluid outlet port;
one or more power electrodes attached to the base plate;
one or more silicon rods disposed substantially in the stainless steel envelope and electrically coupled to the one or more power electrodes; and
a heat radiation system that is annularly disposed in the reactor having at least one heating element which emits thermal radiation having a color temperature of at least 2000° C.;
a steam generator configured to receive the thermal fluid having a temperature of up to 450° C. from the reactor and further configured to receive heat from an external source and generate a super heated steam; and
a steam turbine/generator configured to receive the super heated steam and generate electricity.

31. The enclosed CVD reactor assembly of claim 30, wherein the reactor comprises a double walled chamber.

32. The enclosed CVD rector assembly of claim 30, wherein the thermal fluid is capable of maintaining reactor wall temperature of up to 450° C.
